(19) United States
(12) Patent Application Publication
(10) Pub. No.: US 2026/0317604 A1
(43) Pub. Date: Oct. 15, 2026

(54) POLISHING COMPOSITION

(71) Applicant: FUJIMI INCORPORATED, Kiyosu-shi (JP)

(72) Inventors: Atsushi Sakamoto, Kiyosu-shi (JP); Shota Suzuki, Kiyosu-shi (JP); Tatsuhiko Hirano, Kiyosu-shi (JP); Kazuaki Iwasaki, Kiyosu-shi (JP); Masaaki Ito, Kiyosu-shi (JP); Shogo Tsubota, Kiyosu-shi (JP); Keiji Ashitaka, Kiyosu-shi (JP)

(73) Assignee: FUJIMI INCORPORATED, Kiyosu-shi (JP)

(21) Appl. No.: 19/463,510

(22) Filed: Jan. 29, 2026

(30) Foreign Application Priority Data
Mar. 26, 2025 (JP) 2025-051438

(51) Int. Cl. C09K 3/14

(52) U.S. Cl. CPC C09K 3/1463

(57) ABSTRACT

An object is to provide a polishing composition in which the ratio of the polishing removal rate of a layer containing a nitrogen atom-silicon atom bond such as silicon nitride or the like to the polishing removal rate of a layer containing a silicon atom-oxygen atom bond such as silicon oxide or the like can be increased and stability is kept. A polishing composition for polishing an object to be polished, the polishing composition including an abrasive grains, an acid, and an aqueous carrier, in which the abrasive grains are colloidal silica having an organic acid immobilized on surfaces thereof, the number of silanol groups in the abrasive grains is 3.50/nm² or less, a value obtained by dividing an average primary particle size (nm) of the abrasive grains by the number of silanol groups (/nm²) is 8.00 or more, and a pH is less than 6.0.

### TECHNICAL FIELD

The present disclosure relates to a polishing composition.

### BACKGROUND ART

There are issues of polishing of silicon nitride films poor in chemical reactivity at high rates in semiconductor device manufacturing processes. There are also issues of increases in polishing removal rates of silicon nitride films relative to polishing removal rates of silicon oxide films.

For example, Patent Literature 1 mentions that conventional aqueous dispersions for chemical mechanical polishing have required high polishing pressure and have been problematic in terms of storage stability, and tries to provide a technique for providing an aqueous dispersion for chemical mechanical polishing, which not only can allow the polishing removal rate ratio of a silicon nitride film to a silicon oxide film to be sufficiently large, but also is favorable in storage stability, as well as a chemical mechanical polishing method with the aqueous dispersion.

### CITATION LIST

### Patent Literature

Patent Literature 1: WO 2011/093153

### SUMMARY

### Technical Problem

An object to be achieved by the present disclosure is to provide a technique for controlling the selectivity and keeping stability of a polishing composition by another approach not disclosed in Patent Literature 1. More specifically, an object is to provide a polishing composition in which the ratio of the polishing removal rate of a layer containing a nitrogen atom-silicon atom bond such as silicon nitride to the polishing removal rate of a layer containing a silicon atom-oxygen atom bond such as silicon oxide can be increased and stability is maintained.

### Solution to Problem

There is provided a polishing composition for polishing an object to be polished, the polishing composition including abrasive grains, an acid, and an aqueous carrier, wherein the abrasive grains are colloidal silica having an organic acid immobilized on surfaces thereof, the number of silanol groups in the abrasive grains is 3.50/nm² or less, a value obtained by dividing an average primary particle size (nm) of the abrasive grains by the number of silanol groups (/nm²) is 8.00 or more, and a pH there of is less than 6.0.

### Effect of the Disclosure

According to the present disclosure, it is possible to provide a polishing composition in which the ratio of the polishing removal rate of a layer containing a nitrogen atom-silicon atom bond such as silicon nitride to the polishing removal rate of a layer containing a silicon atom-oxygen atom bond such as silicon oxide can be increased and stability is maintained.

### DESCRIPTION OF EMBODIMENTS

Herein, “X to Y” is used to mean that numerical values (X and Y) described before and after “to” are included as the lower limit value and the upper limit value, and means “X or more and Y or less”. In a case where a plurality of descriptions “X to Y” is made, for example, in a case where “X1 to Y1, or X2 to Y2”, or “X1 or more and Y1 or less, or X2 or more and Y2 or less” is described, all of the disclosure where each numerical value is adopted as the upper limit, the disclosure where each numerical value is adopted as the lower limit, and the disclosure of any combination of such upper limit and lower limit are made (namely, these disclosures serve as legitimate bases for amendments). Specifically, all of respective amendments to X1 or more, Y2 or less, X1 or less, Y2 or more, X1 to X2, X1 to Y2, and the like need to be legitimate. Herein, the description “X or more” means X or more than X and thus encompasses the meaning “more than X”. Similarly, the description “Y or less” means Y or less than Y and thus encompasses the meaning “less than Y”. Unless particularly noted, operations, and measurement of physical properties and the like are made under conditions of room temperature (20 to 25° C.)/relative humidity: 40 to 50% RH. The concentration described herein may be a concentration at POU (Point-of-use) or a concentration before dilution to the concentration at POU. The dilution factor may be 2 to 10-fold. It is to be understood that all combinations of embodiments and descriptions disclosed herein are disclosed in the present application. In other words, it is to be understood that these combinations can serve as legitimate bases for amendments. In a case where the content or the concentration of each component is described and two or more kinds of such components are included, the total amount of such components can be adopted.

### <Polishing Composition>

According to one aspect of the present disclosure, abrasive grains, an acid, and an aqueous carrier are included, the abrasive grains are colloidal silica having an organic acid immobilized on surfaces thereof, and the number of silanol groups in the abrasive grains is 3.50/nm² or less. According to one embodiment of the present disclosure, there is provided a polishing composition for polishing an object to be polished, the polishing composition including abrasive grains, an acid, and an aqueous carrier, wherein the abrasive grains are colloidal silica having an organic acid immobilized on surfaces thereof, the number of silanol groups in the abrasive grains is 3.50/nm² or less, the value obtained by dividing the average primary particle size (nm) of the abrasive grains by the number of silanol groups (/nm²) is 8.00 or more, and the pH thereof is less than 6.0. Thus, the ratio of the polishing removal rate of a layer containing a nitrogen atom-silicon atom bond such as silicon nitride to the polishing removal rate of a layer containing a silicon atom-oxygen atom bond such as silicon oxide (herein, also referred to as “selectivity”) can be increased, and stability can be maintained.

### [Abrasive Grain]

The polishing composition disclosed herein includes abrasive grains. The abrasive grains has the effect of mechanically polishing an object to be polished. The abrasive grains included in the polishing composition disclosed herein are colloidal silica having an organic acid immobilized on surfaces thereof, and the number of silanol groups in the abrasive grains is 3.50/nm² or less. The method for chemically introducing the organic acid to a silica particle surface is not particularly limited, and examples include not only a method including first introducing a thiol group, an alkyl group, a hydroxyl group, an aldehyde group, or the like to a silica particle surface and thereafter oxidizing such a group to an organic acid group such as a sulfonic acid group or a carboxylic acid group, but also a method including introducing an organic acid group in the state of being bound with a protection group, to a silica particle surface, and thereafter desorbing the protection group.

As a specific example, when a sulfonic acid group is immobilized on a silica particle, such immobilization can be performed by, for example, a method described in “Sulfonic acid-functionalized silica through of thiol groups”, Chem. Commun. 246-247 (2003). Specifically, a silica particle that is surface-immobilized with a sulfonic acid group can be obtained by performing surface modification involving coupling a silane coupling agent having a thiol group, such as 3-mercaptopropyl trimethoxysilane, to a silica particle and then oxidizing the thiol group with an oxidizing agent such as hydrogen peroxide. Alternatively, when a carboxylic acid group is immobilized to a silica particle, such immobilization can be performed by, for example, a method described in “Novel Silane Coupling Agents Containing a Photolabile 2-Nitrobenzyl Ester for Introduction of a Carboxy Group on the Surface of Silica Gel”, Chemistry Letters, 3,228-229 (2000). Specifically, a silica particle that is surface-immobilized with a carboxylic acid group can be obtained by performing surface modification involving coupling a silane coupling agent containing a photo-reactive 2-nitrobenzyl ester, to a silica particle, and then irradiating the resultant with light.

According to one embodiment of the present disclosure, when an organic acid is to be introduced onto the surface of silica particles, silica particles having a relatively small number of silanol groups are used as the starting material. Employing such particles markedly reduces the amount of organic acid that must be chemically immobilized on the particle surface, and consequently suppresses any impact on the polishing removal rate that might otherwise result from the elution of organic acid remaining unreacted.

According to one embodiment of the present disclosure, the number of silanol groups in the abrasive grains in the polishing composition is 3.40/nm² or less, 3.30/nm² or less, 3.20/nm² or less, 3.10/nm² or less, 3.00/nm² or less, 2.90/nm² or less, 2.80/nm² or less, 2.70/nm² or less, 2.60/nm² or less, 2.50/nm² or less, 2.40/nm² or less, less than 2.36/nm², 2.30/nm² or less, 2.20/nm² or less, 2.10/nm² or less, 2.00/nm² or less, 1.90/nm² or less, 1.80/nm² or less, or 1.70/nm² or less. The method for measuring the number of silanol groups in the abrasive grains can be a method disclosed in Examples. If the number of silanol groups in the abrasive grains is too large, suppression of the polishing removal rate of the layer containing a silicon atom-oxygen atom bond of silicon oxide or the like is liable to be made impossible. According to one embodiment of the present disclosure, the number of silanol groups in the abrasive grains in the polishing composition is 1.10/nm² or more, 1.20/nm² or more, 1.30/nm² or more, 1.40/nm² or more, 1.50/nm² or more, 1.60/nm² or more, 1.70/nm² or more, 1.80/nm² or more, 1.90/nm² or more, 2.00/nm² or more, 2.10/nm² or more, 2.20/nm² or more, 2.30/nm² or more, 2.60/nm² or more, 2.90/nm² or more, or 3.10/nm² or more. If the number of silanol groups in the abrasive grains is too small, the abrasive grains is liable to be aggregated. The method for controlling the number of silanol groups in the abrasive grains to 3.50/nm² or less, as one example thereof, is, for example, heat treatment with an autoclave, or a method for controlling the molar ratio of the organic acid to be introduced to the silica particle surface. As described above, by using, as the starting material, silica particles that have a comparatively small number of silanol groups prior to introduction of the organic acid, it is possible to suppress the release of organic acid that could otherwise affect the polishing removal rate and, at the same time, obtain colloidal silica in which the relative proportion of surface silanol groups remains high.

The number of silanol groups in the abrasive grains can be determined by using silica particles either before mixing with the other components for preparing a polishing liquid (polishing composition) or from silica particles sampled from a polishing liquid (polishing composition). Because the number of silanol groups of the silica particles undergoes almost no change during preparation of a polishing liquid (polishing composition), the value obtained from the silica particles before mixing or the value obtained from the sampled particles may be used interchangeably.

According to one embodiment of the present disclosure, the lower limit of the average primary particle size of the abrasive grains in the polishing composition is 11.0 nm or more, 12.0 nm or more, 13.0 nm or more, 14.0 nm or more, 15.0 nm or more, 16.0 nm or more, 17.0 nm or more, 18.0 nm or more, 19.0 nm or more, 20.0 nm or more, 21.0 nm or more, 22.0 nm or more, 23.0 nm or more, 24.0 nm or more, 25.0 nm or more, 26.0 nm or more, 27.0 nm or more, 28.0 nm or more, 29.0 nm or more, 30.0 nm or more, 31.0 nm or more, 32.0 nm or more, 33.0 nm or more, 34.0 nm or more, 35.0 nm or more, 36.0 nm or more, 37.0 nm or more, 38.0 nm or more, 39.0 nm or more, 40.0 nm or more, 41.0 nm or more, 42.0 nm or more, or 43.0 nm or more. By increasing the lower limit of the average primary particle size of the abrasive grains, the required selectivity can be ensured while enhancing the polishing removal rate of layers containing nitrogen-silicon bonds, such as silicon nitride.

According to one embodiment of the present disclosure, the upper limit of the average primary particle size of the abrasive grains in the polishing composition is 60.0 nm or less, 55.0 nm or less, 50.0 nm or less, 45.0 nm or less, 44.0 nm or less, 43.0 nm or less, 42.0 nm or less, 41.0 nm or less, 40.0 nm or less, 39.0 nm or less, 38.0 nm or less, 37.0 nm or less, 36.0 nm or less, 35.0 nm or less, 34.0 nm or less, 33.0 nm or less, 32.0 nm or less, 31.0 nm or less, 30.0 nm or less, 29.0 nm or less, 28.0 nm or less, 27.0 nm or less, 26.0 nm or less, 25.0 nm or less, 24.0 nm or less, 23.0 nm or less, 22.0 nm or less, or 21.0 nm or less. By appropriately setting the upper limit of the average primary particle size of the abrasive grains, aggregation of the abrasive grains can be suppressed. According to one embodiment of the present disclosure, the average primary particle size of the abrasive grains in the polishing composition is 11.0 nm or more and 60.0 nm or less. The method for measuring the average primary particle size is according to a method described in Examples.

According to one embodiment of the present disclosure, the lower limit of the average secondary particle size of the abrasive grains in the polishing composition is 21 nm or more, 23 nm or more, 25 nm or more, 27 nm or more, 29 nm or more, 31 nm or more, 33 nm or more, 35 nm or more, 37 nm or more, 39 nm or more, 41 nm or more, 43 nm or more, 50 nm or more, 55 nm or more, or 60 nm or more. By increasing the lower limit of the average secondary particle size of the abrasive grains, the required selectivity can be secured while enhancing the polishing removal rate of layers containing nitrogen-silicon bonds, such as silicon nitride. According to one embodiment of the present disclosure, the upper limit of the average secondary particle size of the abrasive grains in the polishing composition is 100 nm or less, 95 nm or less, 90 nm or less, 85 nm or less, 80 nm or less, 75 nm or less, 70 nm or less, less than 70 nm, 65 nm or less, 60 nm or less, 55 nm or less, 50 nm or less, less than 50 nm, 49 nm or less, 48 nm or less, 47 nm or less, 46 nm or less, 45 nm or less, 44 nm or less, 40 nm or less, or 35 nm or less. By appropriately setting the upper limit of the average secondary particle size of the abrasive grains, aggregation of the abrasive grains can be suppressed. According to one embodiment of the present disclosure, the average secondary particle size of the abrasive grains in the polishing composition is 21 nm or more and 100 nm or less. The method for measuring the average secondary particle size is according to a method described in Examples.

According to one embodiment of the present disclosure, the average degree of association (average secondary particle size (nm)/average primary particle size (nm)) of the abrasive grains in the polishing composition is 1.10 or more, 1.20 or more, 1.30 or more, 1.40 or more, or 1.50 or more. According to one embodiment of the present disclosure, the average degree of association (average secondary particle size (nm)/average primary particle size (nm)) of the abrasive grains in the polishing composition is 2.00 or less, 1.90 or less, 1.80 or less, 1.70 or less, 1.60 or less, 1.50 or less, or 1.40 or less.

According to one embodiment of the present disclosure, the abrasive grains in the polishing composition has a negative zeta potential. The numerical value of such a zeta potential is, for example, −10 mV or less, −15 mV or less, −20 mV or less, −25 mV or less, −30 mV or less, −35 mV or less, −40 mV or less, −45 mV or less, or −50 mV or less. The numerical value of such a zeta potential is, for example, −65 mV or more, −55 mV or more, −50 mV or more, −45 mV or more, −30 mV or more, or −25 mV or more. The numerical value of such a zeta potential is, for example, −65 mV or more and −10 mV or less. The abrasive grains in the polishing composition can have any zeta potential of the above upper limit, the above lower limit, or in the above range, thereby more enhancing the polishing removal rate of the layer containing a nitrogen atom-silicon atom bond of silicon nitride or the like. The zeta potential of the abrasive grains in the polishing composition can be measured by a method described in Examples. This zeta potential can be adjusted, for example, by regulating the amount of anionic groups-particularly organic acid groups-on the abrasive grains and by controlling the pH of the polishing composition.

According to one embodiment of the present disclosure, the concentration of the abrasive grains in the polishing composition is 1.00% by mass or more, 1.50% by mass or more, more than 1.95% by mass, 2.00% by mass or more, 2.50% by mass or more, 3.00% by mass or more, 3.10% by mass or more, 3.20% by mass or more, 3.30% by mass or more, 3.40% by mass or more, 3.50% by mass or more, 3.60% by mass or more, or 3.70% by mass or more. If the concentration of the abrasive grains in the polishing composition is low, enhancement of the polishing removal rate of the layer containing a nitrogen atom-silicon atom bond of silicon nitride or the like is liable to be impossible, and enhancement of the selectivity is liable to be impossible. While the polishing removal rate of a layer containing a nitrogen atom-silicon atom bond such as silicon nitride or the like on a patterned wafer is generally estimated based on the polishing removal rate on a blanket wafer, a low concentration of the abrasive grains may also cause the difference between the polishing removal rate on a blanket wafer and the polishing removal rate on a patterned wafer (reduction in the polishing removal rate on a patterned wafer). Therefore, the concentration of the abrasive grains in the polishing composition is preferably 2.00% by mass or more. According to one embodiment of the present disclosure, the concentration of the abrasive grains in the polishing composition is 10.00% by mass or less, 9.00% by mass or less, 8.00% by mass or less, 7.00% by mass or less, 6.00% by mass or less, less than 6.00% by mass, 5.00% by mass or less, less than 5.00% by mass, less than 4.50% by mass, 4.00% by mass or less, or less than 4.00% by mass. According to one embodiment of the present disclosure, the concentration of the abrasive grains in the polishing composition is 1.00% by mass or more and 10.00% by mass or less. According to one embodiment of the present disclosure, the concentration of the abrasive grains in the polishing composition is more than 1.95% by mass and less than 4.50% by mass. According to one embodiment of the present disclosure, the concentration of the abrasive grains in the polishing composition is 2.00% by mass or more and less than 4.00% by mass. If the concentration of the abrasive grains in the polishing composition is less than 2.00% by mass, in particular 1.95% by mass or less, enhancement of the polishing removal rate of the layer containing a nitrogen atom-silicon atom bond of silicon nitride or the like is liable to be impossible, and if the concentration is 4.00% by mass or more, in particular 4.50% by mass or more, the polishing removal rate of the layer containing an oxygen atom-silicon atom bond is liable to be higher to reduce the polishing removal rate of the layer containing a nitrogen atom-silicon atom bond and the selectivity of the layer containing an oxygen atom-silicon atom bond.

According to one embodiment of the present disclosure, the proportion of the colloidal silica having an organic acid immobilized on surfaces thereof in the abrasive grains included in the polishing composition, is 90% by mass or more, 95% by mass or more, 98% by mass or more, 99% by mass or more, 99.5% by mass or more, or 99.9% by mass or more (upper limit 100% by mass).

According to one embodiment of the present disclosure, the surfaces of the abrasive grains in the polishing composition are modified with a single silane coupling agent.

### (Average Primary Particle Size/Number of Silanol Groups)

According to one embodiment of the present disclosure, the value obtained by dividing the average primary particle size (nm) of the abrasive grains by the number of silanol groups (/nm²) (average primary particle size/number of silanol groups) is 8.00 or more. The requirement “value obtained by dividing the average primary particle size (nm) of the abrasive grains by the number of silanol groups (/nm²) is 8.00 or more” is satisfied when the average primary particle size of the abrasive grains is sufficiently large and the number of silanol groups in the abrasive grains is sufficiently small. When the average primary particle size of the abrasive grains is sufficiently large, the polishing removal rate of the layer containing a nitrogen atom-silicon atom bond of silicon nitride or the like can be increased. In this regard, when the number of silanol groups in the abrasive grains is small, the polishing removal rate of the layer containing a silicon atom-oxygen atom bond of silicon oxide or the like can be decreased. If the average primary particle size/number of silanol groups is less than 8.00, it is liable to be made impossible to increase the ratio of the polishing removal rate of the layer containing a nitrogen atom-silicon atom bond of silicon nitride or the like to the polishing removal rate of the layer containing a silicon atom-oxygen atom bond of silicon oxide or the like.

According to one embodiment of the present disclosure, the average primary particle size/number of silanol groups is 9.00 or more, 10.00 or more, 11.00 or more, 12.00 or more, 13.00 or more, 14.00 or more, 15.00 or more, 16.00 or more, 17.00 or more, 18.00 or more, or 19.00 or more. When average primary particle size/number of silanol groups is particularly 14.00 or more, the polishing removal rate of the layer containing a nitrogen atom-silicon atom bond of silicon nitride or the like can be remarkably enhanced and also the selectivity can be increased. According to one embodiment of the present disclosure, the value obtained by dividing the average primary particle size (nm) of the abrasive grains by the number of silanol groups (/nm²) is 50.00 or less, 40.00 or less, 30.00 or less, or 20.00 or less. Having such an upper limit affords the technical advantage of suppressing the polishing removal rate of layer that contains a silicon atom-oxygen atom bond.

Here, the parameter “average primary particle size/number of silanol groups” expresses the particle size of the abrasive grains in relation to the number of silanol groups. For completeness, the Inventors also considered defining the parameter as “average secondary particle size/number of silanol groups.” However, the average secondary particle size represents the mean size of aggregates formed by aggregation of the primary particles, and the number of primary particles constituting each aggregate is expected to vary. Accordingly, the ratio of the average primary particle size to the number of silanol groups is regarded as the more appropriate parameter.

### [pH and pH Adjusting Agent]

In one embodiment of the present disclosure, the pH of the polishing composition is less than 6.0. In a case where the pH of the polishing composition is 6.0 or more, the polishing removal rate of the layer containing a nitrogen atom-silicon atom bond of silicon nitride or the like is liable to be insufficient. In addition, dissolution or the like of the colloidal silica may occur to cause deterioration in stability. According to one embodiment of the present disclosure, the pH of the polishing composition is 5.8 or less, 5.6 or less, 5.4 or less, 5.2 or less, 5.0 or less, 4.8 or less, 4.6 or less, 4.4 or less, 4.2 or less, 4.0 or less, 3.8 or less, 3.6 or less, 3.4 or less, 3.2 or less, or 3.0 or less. According to one embodiment of the present disclosure, the pH of the polishing composition is 1.0 or more, 1.2 or more, 1.4 or more, 1.6 or more, 1.8 or more, 2.0 or more, 2.2 or more, 2.4 or more, 2.6 or more, or 2.8 or more. According to one embodiment of the present disclosure, the pH of the polishing composition is 1.0 or more and less than 6.0. According to one embodiment of the present disclosure, the pH of the polishing composition is 2.0 or more and 5.0 or less. In one embodiment of the present disclosure, the polishing composition includes a pH adjusting agent for adjustment to the above upper limit pH, the above lower limit pH, or the pH in the above range. The pH adjusting agent can be an acid. Specific examples of the acid usable as the pH adjusting agent include inorganic acids such as hydrochloric acid, sulfuric acid, nitric acid, hydrofluoric acid, boric acid, carbonic acid, hypophosphorous acid, phosphorus acid and phosphoric acid, and organic acids such as formic acid, acetic acid, propionic acid, butyric acid, pentanoic acid, 2-methylbutyric acid, hexanoic acid, 3,3-dimethyl-butyric acid, 2-ethylbutyric acid, 4-methylpentanoic acid, heptanoic acid, 2-methylhexanoic acid, octanoic acid, 2-ethylhexanoic acid, benzoic acid, hydroxyacetic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenylacetic acid and phenoxyacetic acid.

In one embodiment of the present disclosure, the polishing composition may further contain a base for raising the pH when it becomes excessively low during pH. Examples of the base include amines such as aliphatic amines and aromatic amines, organic bases such as quaternary ammonium hydroxide, hydroxides of alkali metals, such as sodium hydroxide and potassium hydroxide, hydroxides of alkali earth metals (Group 2 elements), and ammonia.

In one embodiment of the present disclosure, the amount of the pH adjusting agent (for example, acid) included in the polishing composition is an appropriate amount for providing the above upper limit pH, the above lower limit pH, or the pH in the above range. The pH of the polishing composition can be measured with, for example, a pH meter, and specifically can be measured by a method described in Examples.

### [Liquid Carrier]

The polishing composition disclosed herein includes an aqueous carrier. The aqueous carrier preferably includes water. According to one embodiment of the present disclosure, the aqueous carrier may optionally contain alcohols such as methanol, ethanol, or ethylene glycol, ketones such as acetone, and the like; however, water preferably makes up at least 90 mass %, more preferably at least 95 mass %, still more preferably at least 98 mass %, 99 mass %, 99.5 mass %, or even 99.9 mass % of the carrier, with an upper limit of 100 mass %.

### [Other Components]

According to one embodiment of the present disclosure, the polishing composition may or may not further include, if necessary, any other component such as a water-soluble polymer, a complexing agent, a metal anticorrosive, an antiseptic agent, a reducing agent, and/or a surfactant.

### (Antiseptic Agent)

According to one embodiment of the present disclosure, the polishing composition can be an aqueous liquid, and thus microorganisms (bacteria and/or mold) are easily developed and stability can be lost during long-term storage or use. Therefore, an antiseptic agent can be added, and an antiseptic agent having the function of suppression of development of microorganisms (bacteria and/or mold) can be included. Examples of such an antiseptic agent include isothiazoline-based antiseptic agents such as 2-methyl-4-isothiazolin-3-one and 5-chloro-2-methyl-4-isothiazolin-3-one, paraoxybenzoic acid esters, and phenoxyethanol. Such antiseptic agents and antifungal agents may be each used singly or in combinations of two or more kinds thereof.

According to one embodiment of the present disclosure, the polishing composition does not contain both an inorganic salt such as an ammonium salt and an organic salt (detection limit or less), or at least one of these salts, even if contained, is at less than 0.05% by mass or less than 5 mM. Such an embodiment can increase the selectivity. The ammonium salt may be an inorganic acid salt or an organic acid salt, and examples of the inorganic acid salt include ammonium sulfate, ammonium nitrate, ammonium chloride, ammonium fluoride, ammonium borate, ammonium carbonate, diammonium hydrogen carbonate, ammonium dihydrogen carbonate, ammonium hypophosphite, ammonium phosphite, and ammonium phosphate. Examples of the organic acid salt include ammonium formate, ammonium acetate, ammonium propionate, ammonium butyrate, ammonium valerate, ammonium benzoate, ammonium glycolate, ammonium salicylate, ammonium glycerate, ammonium oxalate, ammonium malonate, ammonium succinate, ammonium glutarate, ammonium adipate, ammonium pimelate, ammonium maleate, ammonium phthalate, ammonium malate, ammonium tartrate, diammonium hydrogen citrate, triammonium citrate, ammonium lactate, and ammonium diglycolate.

### [Object to be Polished]

In one embodiment of the present disclosure, the object to be polished has a layer containing an oxygen-silicon bond. Examples of such a layer include a TEOS-type silicon oxide (hereinafter, also simply referred to as ““TEOS” or “silicon dioxide”) produced with tetraethyl orthosilicate as a precursor, HDP (High Density Plasma), USG (Undoped Silicate Glass), PSG (Phosphorus Silicate Glass), BPSG (Boron-Phospho Silicate Glass), or RTO (RaPID Thermal Oxidation). Such a TEOS film can be formed by plasma CVD.

In one embodiment of the present disclosure, the object to be polished has a layer containing a nitrogen atom-silicon atom bond. Examples of such a layer include a silicon nitride film or SiCN (silicon carbonitride).

### [Method for Producing Polishing Composition]

According to one embodiment of the present disclosure, the polishing composition can be obtained by, for example, stirring and mixing the abrasive grains, the acid, and the aqueous carrier disclosed herein, and any other additive if necessary added. The details of these components are as described above. The temperature during mixing of these components is not particularly limited, and is preferably 10° C. or more and 40° C. or less, and heating may be made in order to increase the rate of dissolution. The mixing time is also not particularly limited as long as uniform mixing can be achieved.

### [Polishing Method and Method for Producing Semiconductor Substrate]

The polishing composition disclosed herein is particularly suitably used for polishing of an object to be polished having a layer containing a nitrogen atom-silicon atom bond such as silicon nitride. Accordingly, there is herein provided a polishing method including polishing an object to be polished having a layer containing a nitrogen atom-silicon atom bond such as silicon nitride, with the polishing composition disclosed herein. The polishing composition disclosed herein is particularly suitably used for polishing of an object to be polished having a layer containing an oxygen-silicon bond and a layer containing a nitrogen-silicon bond. Accordingly, there is herein provided a polishing method including polishing an object to be polished having a layer containing an oxygen-silicon bond and a layer containing a nitrogen-silicon bond, with the polishing composition disclosed herein.

While a conventional polishing apparatus can be used, it is preferable to employ a polishing apparatus capable of precisely controlling the polishing conditions and stably ensuring the in-plane uniformity of the wafer. Whether the “in-plane uniformity of a wafer can be stably ensured” can be judged, for example, from the low non-uniformity value calculated by Equation (1) using the average polishing removal rate (R) measured at 49 points along the wafer diameter and the standard deviation (σ) of those 49 rates.

Non-uniformity (%)=(σ/R)×100 (Formula 1).

The Non-uniformity (%) is, for example, 5% or less, 3% or less, or 1% or less. The practical lower limit is more than 0%.

The polishing apparatus used here can be a common polishing apparatus in which a holder for holding a substrate or the like having an object to be polished, a motor changeable in the number of rotations, and the like are installed and which has a polishing table (platen) to which a polishing pad (polishing cloth) can be attached. The polishing pad used here can be, for example, a common unwoven cloth, polyurethane, and a porous fluororesin, without particular limitations. The polishing pad is preferably grooved so as to allow the polishing liquid to be accumulated. Among polishing conditions, for example, the rotational rate of the polishing table (platen) and the carrier (head) is preferably 10 rpm or more and 200 rpm or less, 20 rpm or more and less than 117 rpm, 30 rpm or more and 110 rpm or less, 40 rpm or more and 100 rpm or less, or 50 rpm or more and 90 rpm or less. When the polishing composition disclosed herein is used, the polishing removal rate of an object to be polished can be enhanced even at a low rotational rate of the polishing table (platen) and the carrier (head) in the polishing apparatus used for polishing. The pressure (polishing pressure) applied to a substrate having the object to be polished is preferably 0.5 psi or more and 10 psi or less, more preferably 1.0 psi or more and 6.0 psi or less, further preferably 1.5 psi or more and 4.0 psi or less, still further preferably 2.0 psi or more and 3.8 psi or less, still further preferably 2.1 psi or more and 3.5 psi or less, still further preferably 2.2 psi or more and 3.0 psi or less. In particular, when the polishing pressure applied to the substrate having the object to be polished is at least 2.1 psi, the ratio of the polishing removal rate of a layer containing a nitrogen atom-silicon atom bond such as silicon nitride to the polishing removal rate of a layer containing a silicon atom-oxygen atom bond such as silicon oxide can be increased. At the same time, the stability of the polishing composition is maintained, and the throughput-namely, the number of wafers that can be processed per unit time—can be further improved.

The method for supplying the polishing composition to the polishing pad is also not particularly limited, and, for example, a method of continuously supplying with a pump or the like is adopted. The amount of supply is not limited, and a surface of the polishing pad is preferably always covered with the polishing composition according to the present disclosure.

### [Polishing Removal Rate]

The polishing removal rate disclosed herein can be measured in conditions described in Examples.

The polishing composition disclosed herein can allow a layer containing a nitrogen-silicon bond to be polished at a high polishing removal rate. According to one embodiment of the present disclosure, the polishing composition has the property of exhibiting a polishing removal rate of a layer containing a nitrogen-silicon bond, of 300 Å/min or more, 320 Å/min or more, 340 Å/min or more, 360 Å/min or more, 380 Å/min or more, 400 Å/min or more, 420 Å/min or more, 440 Å/min or more, 460 Å/min or more, 480 Å/min or more, 500 Å/min or more, 520 Å/min or more, 540 Å/min or more, or 560 Å/min or more. High-rate polishing of chemically inert silicon nitride is preferred because it enhances process productivity. According to one embodiment of the present disclosure, the polishing composition has the property of exhibiting a polishing removal rate of a layer containing a nitrogen-silicon bond, of 1000 Å/min or less, 800 Å/min or less, or 600 Å/min or less. Note: 1 Å=0.1 nm.

The polishing composition disclosed herein can allow a layer containing an oxygen-silicon bond to be polished at a low polishing removal rate. According to one embodiment of the present disclosure, the polishing composition has the property of exhibiting a polishing removal rate of a layer containing an oxygen-silicon bond, of 200 Å/min or less, 180 Å/min or less, 160 Å/min or less, 140 Å/min or less, 120 Å/min or less, 100 Å/min or less, 90 Å/min or less, 80 Å/min or less, 70 Å/min or less, or 60 Å/min or less. According to one embodiment of the present disclosure, the polishing composition has the property of exhibiting a polishing removal rate of a layer containing an oxygen-silicon bond, of 30 Å/min or more, 40 Å/min or more, 50 Å/min or more, or more than 55 Å/min. When the foregoing lower limit is employed, the polishing composition can be preferably used in high-k gate-insulator polishing processes, because it allows the second layer containing nitrogen-silicon bonds to be polished at a high polishing removal rate while still ensuring an adequate process window for controlling the removal amount of the first layer containing oxygen-silicon bonds. Here, the term “process window” denotes, for example, the range of process conditions needed to remove only a small amount of the underlying oxygen-silicon-bonded layer (e.g., a TEOS layer). If the polishing removal rate is too low, the polishing time becomes long and productivity deteriorates; if the polishing removal rate is too high, it becomes difficult to control the removal amount. The following example illustrates the difficulty that arises when the polishing removal rate is excessively high. Suppose the target is to remove 50 Å of a TEOS film. At a polishing removal rate of 500 Å/min (too high), a one-second deviation in polishing time produces an 8 Å error in the removal amount. By contrast, at a polishing removal rate of 50 Å/min, the same one-second deviation results in an error of less than 1 Å. Accordingly, in processes such as high-k gate-insulator CMP, where only a small amount of an oxygen-silicon-bonded layer (e.g., TEOS) must be removed, it is desirable for the polishing removal rate to be high enough to improve productivity, yet adjusted so as not to become excessively high.

### [Selectivity]

According to one embodiment of the present disclosure, the polishing composition has the property of exhibiting a ratio of the polishing removal rate (Å/min) of a layer containing a nitrogen-silicon bond to the polishing removal rate (Å/min) of a layer containing an oxygen-silicon bond, of more than 3.40, more than 4.00, 4.20 or more, 4.40 or more, more than 4.40, 4.60 or more, 4.80 or more, 5.00 or more, 5.20 or more, 5.40 or more, more than 5.53, 5.60 or more, 5.80 or more, 6.00 or more, 6.20 or more, 6.40 or more, 6.60 or more, 6.80 or more, 7.00 or more, 7.20 or more, 7.40 or more, 7.60 or more, 7.70 or more, 8.00 or more, 8.20 or more, 8.40 or more, 8.60 or more, or 8.80 or more. According to one embodiment of the present disclosure, the polishing composition has the property of exhibiting a ratio of the polishing removal rate (Å/min) of a layer containing a nitrogen-silicon bond to the polishing removal rate (Å/min) of a layer containing an oxygen-silicon bond, of 9.00 or less, less than 8.96, 8.50 or less, 8.00 or less, 7.50 or less, 7.00 or less, 6.50 or less, 6.00 or less, 5.60 or less, or 5.00 or less. When the selectivity is limited in this way—particularly when it is 8.00 or less—the polishing composition can be advantageously used in high-k gate-insulator polishing processes. Under this upper limit, it is possible to polish the second layer containing nitrogen-silicon bonds at a high rate while still securing an adequate process window for controlling the removal amount of the first layer containing oxygen-silicon bonds.

The present disclosure includes the following aspects and embodiments.
1. A polishing composition for polishing an object to be polished, the polishing composition comprising abrasive grains, an acid, and an aqueous carrier, wherein the abrasive grains are colloidal silica having an organic acid immobilized on surfaces thereof, the number of silanol groups in the abrasive grains is 3.50/nm² or less, a value obtained by dividing an average primary particle size (nm) of the abrasive grains by the number of silanol groups (/nm²) is 8.00 or more, and a pH thereof is less than 6.0.
2. The polishing composition according to 1., wherein the object to be polished has a layer containing a nitrogen-silicon bond.
3. The polishing composition according to 2., wherein the object to be polished has a layer containing an oxygen-silicon bond and a layer containing a nitrogen-silicon bond.
4. The polishing composition according to 3., wherein a ratio of a polishing removal rate (Å/min) of the layer containing the nitrogen-silicon bond to a polishing removal rate (Å/min) of the layer containing the oxygen-silicon bond is more than 3.40.
5. The polishing composition according to any of 1. to 4., wherein the pH is 2.0 or more and 5.0 or less.
6. The polishing composition according to any of 1. to 5., wherein the number of silanol groups in the abrasive grains is 2.00/nm² or less.
7. The polishing composition according to any of 1. to 6., wherein a concentration of the abrasive grains is 2.00% by mass or more.
8. The polishing composition according to any of 1. to 7., wherein a ratio of an average secondary particle size (nm) of the abrasive grains to the average primary particle size (nm) of the abrasive grains is 1.8 or less.

### EXAMPLES

The present disclosure is described in further detail with reference to the following Examples and Comparative Examples. It is noted that the technical scope of the present disclosure is not limited to only the following Examples. Unless particularly noted, “%” and “part(s)” respectively mean “% by mass” and “part(s) by mass”. In the following Examples, operations were performed under conditions of room temperature (20° C. or more and 25° C. or less)/relative humidity: 40% RH or more and 50% RH or less, unless particularly noted. Herein, each of physical properties was measured as follows.

### <Average Primary Particle Size of Abrasive Grains>

The average primary particle size of the abrasive grains was calculated from the specific surface area of silica particles according to a BET method, as measured with ““Flow Sorb II 2300” manufactured by Micromeritics Instrument Corporation, and the density of the abrasive grains.

### <Average Secondary Particle Size of Abrasive Grains>

The average secondary particle size of the abrasive grains was measured as the volume average particle size (arithmetic average size on volume basis; Mv) with a dynamic light-scattering type particle size/particle size distribution apparatus UPA-UT151 (manufactured by Nikkiso Co., Ltd.).

### <Zeta Potential of Abrasive Grains>

The zeta potential of the abrasive grains in the polishing composition was calculated by using Zetasizer Nano manufactured by Malvern Panalytical Ltd., measurement by a laser Doppler method (electrophoretic light scattering measurement method) under a condition of a measurement temperature of 25° C., and analysis of the resulting data by the Smoluchowski equation.

### <pH of Polishing Composition>

The pH of the polishing composition was obtained as the pH value being the value after three-point calibration with a glass electrode-type hydrogen ion concentration indicator (Model number: F-23 manufactured by Horiba Ltd.) and a standard buffer (phthalate pH buffer pH: 4.01 (25° C.), neutral phosphate pH buffer pH: 6.86 (25° C.), carbonate pH buffer pH: 10.01 (25° C.)) and then placement of the glass electrode in the polishing composition and a lapse of 2 minutes or more for stabilization.

### <Method for Calculating Number of Silanol Groups>

The number of silanol groups per unit surface area (unit: /nm²) of the abrasive grains was calculated by the following method after measurement or calculation of each parameter by the following measurement method or calculation method.

More specifically, C in the following formula represents the total mass of the abrasive grains, and S in the following formula represents the BET specific surface area of the abrasive grains. Further specifically, first, 1.50 g of the abrasive grains as a solid content is taken in a 200-ml beaker and 100 ml of pure water is added to provide a slurry, and thereafter 30 g of sodium chloride is added and dissolved. Next, 1 N hydrochloric acid is added to adjust the pH of the slurry to 3.0 to 3.5, and thereafter pure water is added until 150 ml of the slurry is obtained.

An automatic titration apparatus (COM-1700 manufactured by Hiranuma Co., Ltd.) is used in the slurry to adjust the pH to 4.0 with 0.1 N sodium hydroxide at 25° C., and furthermore measure the volume V [L] of a 0.1 N sodium hydroxide solution necessary for an increase in pH from 4.0 to 9.0 by pH titration. The average silanol group density (number of silanol groups) can be calculated by the following formula.

ρ=(c×V×N_{A})/(C×S)
wherein
ρ represents the average silanol group density (number of silanol groups) (/nm²);
c represents the concentration (mol/L) of the sodium hydroxide solution used for titration;
V represents the volume (L) of the sodium hydroxide solution necessary for an increase in pH from 4.0 to 9.0;
N_{A} represents the Avogadro constant (molecules/mol);
C represents the total mass of the abrasive grains (solid content) (g); and
S represents the weighted average value (nm²/g) of the BET specific surface area of the abrasive grains. The BET specific surface area is the value of the specific surface area of the abrasive grains by a BET method, as measured with “Macsorb (registered trademark) HM model-1210” manufactured by Mountech Co., Ltd.

### Production of Polishing Composition

### Example 1

A polishing composition was prepared by mixing colloidal silica as the abrasive grains, an acid, and water so that a compositional ratio shown in Table 1 was achieved. Specifically, the polishing composition of Example 1 was prepared by mixing colloidal silica having a sulfonic acid immobilized on its surface and having an average primary particle size of 31.2 nm, an average secondary particle size of 43 nm, and a number of silanol groups of 1.64/nm², together with maleic acid and water, so as to obtain the composition shown in Table 1.

### Examples 2 to 3 and Comparative Example 1

Each polishing composition was prepared in the same manner as in Example 1 except that the size and the number of silanol groups of the colloidal silica having sulfonic acid immobilized on its surface were changed to those shown in Table 1.

### Comparative Example 2

A polishing composition was prepared in the same manner as in Example 1 except that the type of the colloidal silica was changed to unmodified colloidal silica shown in Table 1, which had no sulfonic acid immobilized on its surface.

### Example 4

A polishing composition was prepared in the same manner as in Example 1 except that the concentration of the colloidal silica was changed as shown in Table 1.

### Example 5

A polishing composition was prepared in the same manner as in Example 1 except that the concentration of the colloidal silica was changed as shown in Table 1.

### [Evaluation]

The following (1) and (2) were each prepared as an object to be polished, and polishing was performed according to the following conditions:
(1) Silicon nitride film (SiN film): silicon wafer (200 mm, blanket wafer) with silicon nitride film (SiN film) of 2000 Å in thickness formed on surface thereof
(2) Silicon oxide film (TEOS film): silicon wafer (200 mm, blanket wafer) with TEOS-type silicon oxide (SiO₂) film of 10000 Å in thickness formed on surface thereof.

### (Polishing Apparatus and Polishing Conditions)

Polishing apparatus: CMP single-side polishing apparatus Mirra (for 200 mm) manufactured by Applied Materials, Inc.
Polishing pad: hard polyurethane pad IC1010 manufactured by Nitta Haas Corporation
Polishing pressure: 2.5 psi (1 psi=6894.76 Pa)
Number of rotations of polishing table: 47 rpm
Number of rotations of head (carrier): 43 rpm
Supply of polishing composition: continuous flowing
Amount of supply of polishing composition: 200 mL/min
Polishing time: 60 seconds.

### <Polishing Removal Rate>

The respective thicknesses before and after polishing of each object to be polished were determined with an optical film thickness measuring instrument (ASET-f5x: manufactured by KLA-Tencor Corporation). The film thickness was determined with an optical film thickness measuring instrument (ASET-f5x: manufactured by KLA-Tencor Corporation).

The polishing removal rate in each object to be polished was calculated by dividing the difference in film thickness before and after polishing [(thickness before polishing)−(thickness after polishing)] of such each object to be polished by the polishing time.

### <Dispersion Stability>

The polishing composition was placed in a 100-ml plastic bottle, and stored under an environment at 25° C. for one week. After this storage, visual confirmation was made. The presence or absence of a precipitate was confirmed, and a case where such a precipitate was generated was determined as Aggregated.
Good: no generation of precipitate.
Aggregated: generation of precipitate.

### [Table 1]

TABLE 1

| | Abrasive grains | | | | | |
|---|---|---|---|---|---|---|
| | | Number | Average | Average | | |
| | | of silanol | primary | secondary | Concentration | |
| | | groups | particle | particle | of abrasive | |
| | | (SiOH) | size (PPS) | size (SPS) | grains | |
| | modified or not | [/nm²] | [nm] | [nm] | [% by mass] | PPS/SiOH |
| Ex. 1 | Sulfonic acid-immobilized | 1.64 | 31.2 | 43 | 3.75 | 19.03 |
| Ex. 2 | Sulfonic acid-immobilized | 2.36 | 20.1 | 31 | 3.75 | 8.49 |
| Ex. 3 | Sulfonic acid-immobilized | 3.38 | 44.2 | 64 | 3.75 | 13.05 |
| Ex. 4 | Sulfonic acid-immobilized | 1.64 | 31.2 | 43 | 1.95 | 19.03 |
| Ex. 5 | Sulfonic acid-immobilized | 1.64 | 31.2 | 43 | 4.50 | 19.03 |
| Comp. 1 | Sulfonic acid-immobilized | 5.34 | 35.8 | 68 | 3.75 | 6.71 |
| Comp. 2 | Unmodified | 1.64 | 31.2 | 48 | 3.75 | 19.03 |

| | Abrasive grains | | | | | | |
|---|---|---|---|---|---|---|---|
| | Zeta | pH | | Polishing removal rate | | Selectivity | |
| | potential | adjusting | pH | TEOS | SiN | SiN/TEOS | Dispersion |
| | [mV] | agent (acid) | [—] | [Å/min] | [Å/min] | [—] | stability |
| Ex. 1 | −27.75 | Maleic acid | 3.0 | 85 | 573 | 6.74 | Good |
| Ex. 2 | −27.78 | Maleic acid | 3.0 | 55 | 493 | 8.96 | Good |
| Ex. 3 | −52.22 | Maleic acid | 3.0 | 89 | 362 | 4.07 | Good |
| Ex. 4 | −27.75 | Maleic acid | 3.0 | 78 | 430 | 5.53 | Good |
| Ex. 5 | −27.75 | Maleic acid | 3.0 | 121 | 575 | 4.75 | Good |
| Comp. 1 | −55.00 | Maleic acid | 3.0 | 204 | 365 | 1.79 | Good |

| | | | | | |
|---|---|---|---|---|---|
| Comp. 2 | 9.66 | Maleic acid | 3.0 | Unmeasurable due | Aggregated |
| | | | | to abrasive grains | |
| | | | | aggregation | |

Ex.: Example
Comp.: Comparative Example

### CONCLUSION

According to Examples, it is possible to provide a polishing composition in which the ratio of the polishing removal rate of a layer containing a nitrogen atom-silicon atom bond such as silicon nitride or the like to the polishing removal rate of a layer containing a silicon atom-oxygen atom bond such as silicon oxide or the like can be increased and stability is maintained.

In comparison of Example 1 with Example 2, Example 2 demonstrates more superior selectivity, but exhibited totally lowered polishing removal rates of SiN and TEOS. Accordingly, it can be said that the polishing composition of Example 1 is more superior.

In comparison of Example 1 with Example 3, Example 1 demonstrates more superior selectivity not only from the viewpoint of the polishing removal rate, but also from the viewpoint of the productivity.

The concentration of the abrasive grains in the polishing composition of Example 4 is lower than that of Example 1. Therefore, the polishing removal rate of TEOS in Example 4 was kept lower than that in Example 1, but was also lowered in the polishing removal rate of SiN. As a result, the selectivity of Example 4 was smaller than that of Example 1. Therefore, it can be said that the polishing composition of Example 1 is more superior to that of Example 4.

The concentration of the abrasive grains in the polishing composition of Example 5 is higher than that of Example 1. Example 5 was an example prepared to be expected to be increased in the polishing removal rate of SiN, but the polishing removal rate of SiN was unexpectedly saturated. On the other hand, the polishing removal rate of TEOS was increased, resulting in a lowered selectivity. Therefore, it can be said that the polishing composition of Example 1 is more superior to that of Example 5.

From the foregoing, the polishing composition of Example 1 is most superior among all of the Examples.

Comparative Example 1 is an example with an abrasive grains in which the number of silanol groups is more than 3.50/nm² and the value obtained by dividing the average primary particle size (nm) by the number of silanol groups (/nm²) is less than 8.00. As a result, the polishing removal rate of TEOS was increased, and the selectivity could not be enhanced. Therefore, it is considered that these parameters are important for solving the problems disclosed herein.

The abrasive grains used in the polishing composition of Comparative Example 2 was unmodified and thus the abrasive grains was aggregated.

The present application is based on Japanese Patent Application No. 2025-051438 filed on Mar. 26, 2025, the disclosure of which is herein incorporated by reference in its entirety.

1. A polishing composition for polishing an object to be polished, the polishing composition comprising abrasive grains, an acid, and an aqueous carrier, wherein
the abrasive grains are colloidal silica having an organic acid immobilized on surfaces thereof,
the number of silanol groups in the abrasive grains is 3.50/nm² or less,
a value obtained by dividing an average primary particle size (nm) of the abrasive grains by the number of silanol groups (/nm²) is 8.00 or more, and
a pH thereof is less than 6.0.

2. The polishing composition according to claim 1, wherein the object to be polished has a layer containing a nitrogen-silicon bond.

3. The polishing composition according to claim 2, wherein the object to be polished has a layer containing an oxygen-silicon bond and a layer containing a nitrogen-silicon bond.

4. The polishing composition according to claim 3, wherein a ratio of a polishing removal rate (Å/min) of the layer containing a nitrogen-silicon bond to a polishing removal rate (Å/min) of the layer containing an oxygen-silicon bond is more than 3.40.

5. The polishing composition according to claim 1, wherein the pH is 2.0 or more and 5.0 or less.

6. The polishing composition according to claim 1, wherein the number of silanol groups in the abrasive grains is 2.00/nm² or less.

7. The polishing composition according to claim 1, wherein a concentration of the abrasive grains is 2.00% by mass or more.

8. The polishing composition according to claim 1, wherein a ratio of an average secondary particle size (nm) of the abrasive grains to the average primary particle size (nm) of the abrasive grains is 1.8 or less.
